(19) United States
(12) Patent Application Publication
(10) Pub. No.: US 2006/0294280 A1
(43) Pub. Date: Dec. 28, 2006

(54) Rack server having a rack case having two opposite surfaces installed with a plurality of slots

(75) Inventors: Banks Chen, Taipei (TW); Margaret Chen, Taipei (TW); Tsung-Bin Tsai, Taipei (TW); Chun-Liang Lee, Taipei (TW)

Correspondence Address: EDWARDS & ANGELL, LLP, P.O. BOX 55874, BOSTON, MA, 02205, US

(73) Assignee: Inventec Corporation, Taipei (TW)

(21) Appl. No.: 11/269,928

(22) Filed: Nov. 8, 2005

(30) Foreign Application Priority Data
Jun. 28, 2005 (TW) 094210847

(51) Int. Cl. G06F 13/00; H05K 7/10

(52) U.S. Cl. 710/301

(57) ABSTRACT

A rack server is proposed that includes a rack case, at least a server, and at least an extended interface card. The rack case includes a front surface having a plurality of server slots for insertion of a plurality of servers, and a rear surface having a plurality of card slots corresponding to the server slots for insertion of a plurality of extended interface cards. The server is inserted into one of the server slots and has a rear end connected to a server connector. The extended interface card is inserted into one of the card slots and has a card connector for electrically connecting to the server connector of the server. Therefore, by interconnecting the card connector of extended interface card with the server connector of the server, the extended interface card can be connected to the rear end of the server and a serial relationship is formed such that the extended interface card does not occupy any space where the server slots are installed and a number of slots installed in a unit area will be increased. Meanwhile, manufacturing costs are correspondingly reduced with increasing expansions of the server.

### BACKGROUND OF THE INVENTION

1. Field of the Invention

The present invention relates to rack servers, and more particularly, to a rack server having a rack case having two opposite surfaces each formed with a plurality of slots.

2. Description of Related Art

As the requirement and production of information in an enterprise increase rapidly, a blade server is developed to integrate various servers to provide an enterprise with a great deal of information required in order to handle enormous information communications of enterprise to enterprise, enterprise to customer, or enterprise to other information providers. And since the blade server has such a small volume that it can save spaces and has flexibility in adjusting operating resources. In other words, it provides a user to plug a whole server to one of the slots of a substrate board by a simple way such as inserting a card. Thus, the requirements of expansions and upgrades in an enterprise may be gradually enhanced.

A blade server is a kind of compact server, and is usually installed in a specific rack. In view of the main structure of a blade server, though it can reduce the space costs required for a server, there is a relative increase in the expansion costs. FIG. 11 shows a conventional rack server 200. The rack server 200 includes a rack case 4 and a plurality of blade servers 5. The rack case 4 has a plurality of slots 40 for placement of the blade servers 5. Each of the servers 5 comprises a rear plate 50 installed perpendicularly to a side board of the blade server 5. The rear plate 50 has a connecting interface for connection of an extended interface card 6 such as a peripheral component interconnect-enhanced (PCI-E) card, so as to expand functions of the blade servers 5. Since the rear plate 50 is installed perpendicularly to the side board of the blade server 5, when the rear plate 50 is connected to the extended interface card 6 such as the PCI-E card, the extended interface card 6 is installed in parallel with the blade server 5 in the slots 40 and occupies a space where one of the slots is installed in rack server 200. In equivalent, a number of the slots 40 of the rack server 200 is reduced. In consequence, the expansion amounts of the server are limited, and the manufacturing costs would increase for additionally equipping a structure of the rear plate 50.

Therefore, how to increase the expansion amounts and density of slots of the server and save manufacturing costs at the same time is an urgent task to be solved presently.

### SUMMARY OF THE INVENTION

In consideration of the above drawbacks in the prior art, the primary objective of the present invention is to provide a rack server that can increase the slot amounts of the rack server and enhance a number of slots installed in a unit area of the server.

Another objective of the present invention is to provide a rack server that can reduce the manufacturing costs.

To achieve the above and other objections, the present invention provides a rack server, which includes a rack case, at least a server, and at least an extended interface card. The rack case includes a front surface having a plurality of server slots for insertion of a plurality of servers, and a rear surface having a plurality of card slots corresponding to the server slots for insertion of a plurality of extended interface cards. The server is inserted into one of the server slots and has a rear end connected to a server connector. The extended interface card is inserted into one of the card slots and has a card connector for electrically connecting to the server connector of the server. Preferably, the server is a blade server and the extended interface card is a PCI-E card.

Preferably, the server connector of the server is a slot, and the card connector of the extended interface card is a plugging terminal.

Accordingly, the rack server of the present invention can effectively solve the conventional problems which the PCI-E card like extended interface card is aligned with the blade server in slots and occupy one slot space of the rack server such that reduces the amount of slot of the rack server. Furthermore, the expansion amounts of the server are limited, and the manufacturing costs would be increased for additionally equipping a structure of the rear plate. Therefore, by interconnecting the connector of extended interface card to the connector of the server, the extended interface card connects to the rear end of the server and a serial relationship is formed such that the extended interface card does not occupy the space of a server slot and a number of slots installed in a unit area will be increased. Meanwhile, manufacturing costs may also be saved with increasing expansions of the server accordingly.

The examples of the present invention are illustrated with the following specific embodiments, and a skilled person in the art can easily realize the advantages and effectiveness of the present invention according to the disclosed contents in the specification. The present invention may be executed or applied with other different embodiments, and any details in the specification may be modified or varied based on different points of view and applications without departing from the spirit.

### BRIEF DESCRIPTION OF DRAWINGS

FIG. 1 is a schematic diagram of a rack server according to the prior art;

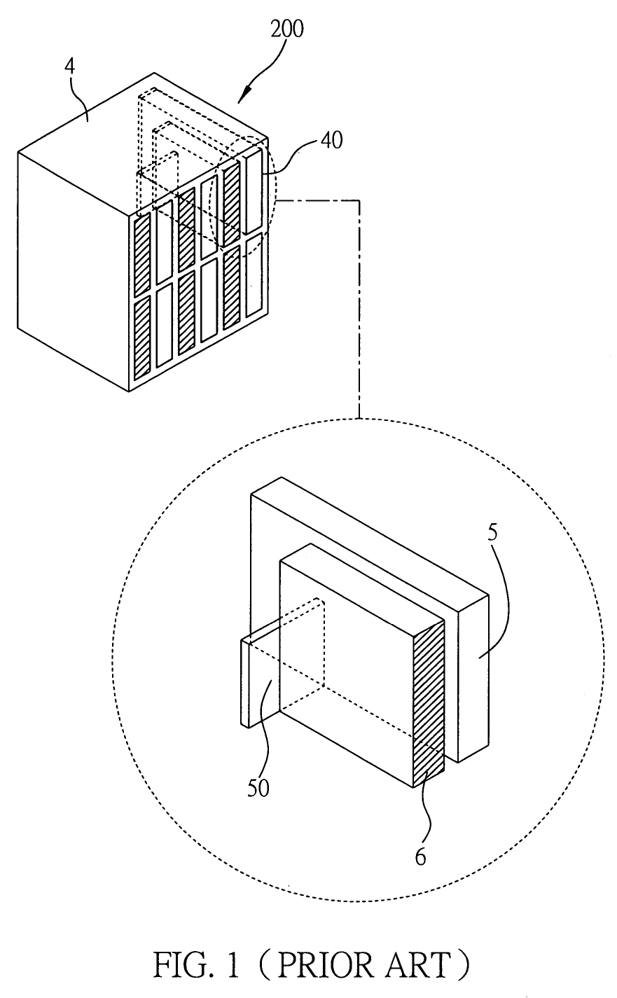

FIG. 2 is a schematic diagram a rack server of the preferred embodiment according to the present invention; and

FIG. 3 is a schematic diagram of a server and an extended interface card of the rack server shown in FIG. 2.

### DETAILED DESCRIPTION OF PREFERRED EMBODIMENTS

The following examples are provided to further illustrate the technical methods of the present invention, and are not to limit the scope of the invention.

In the following examples, a rack server related to the present invention is illustrated with a blade server and a PCI-E card as examples. It should be understood that the rack server is common to a person having general knowledge in the technical field and can include any kind of the servers and extended interface cards not limited by a blade server and a PCI-E card.

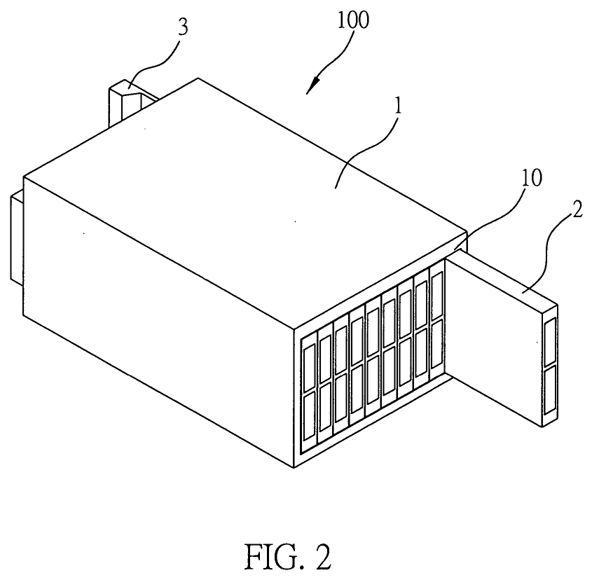

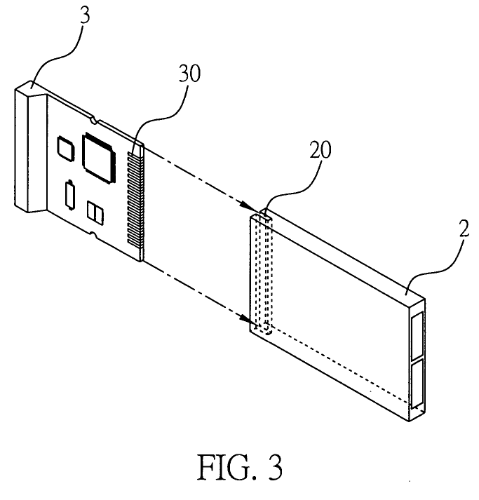

FIG. 2 is a schematic diagram of a rack server 100 of the preferred embodiment according to the present invention. The rack server 100 comprises a rack case 1, at least a server and at least an extended interface card 3. The rack case 1 comprises a front surface having a plurality of server slots 10 for insertion of a plurality of servers such as the server 210, and a rear surface having a plurality of card slots corresponding to the server slots for insertion of a plurality of extended interface cards such as the extended interface card 3. The server 2 is inserted into one of the server slots 10 and has a server connector 20 (shown in FIG. 3) for connecting to a rear end of the server 2. The extended interface card 3 is inserted into one of the card slots, the card slot corresponding to the server slot 10 into which the server 2 is inserted, and has a card connector 30 (shown in FIG. 3) for electrically connecting to the server connector 20 of the server 2.

FIG. 3 is a schematic diagram illustrating the server 2 and the extended interface card 3 of the rack server 100 of the present invention. According to the preferred embodiment, the server 2 is a blade server and the extended interface card 3 is a peripheral component interconnect-enhanced card (PCI-E card), the server connector 20 of the blade server 2 is a slot, and the card connector 30 of the PCI-E card 3 is a plugging terminal for being inserted into the server slot 20 of the blade server 2, so as to electrically connect the PCI-E card 3 to the blade server 2.

When the blade server 2 and the PCI-E card 3 are installed in the rack server 100, by plugging the plugging terminal 30 of the PCI-E card 3 into the server slot 20 on the rear end of the blade server 2, the PCI-E card 3 and the blade server 2 are interconnected to form a serial relationship. And then the connected PCI-E card 3 and blade server 2 are inserted into the server slot 10 of the rack server 100 to complete the fabrication of the rack server 100. According to the preferred embodiment, the server connectors 20 of the server 2 is able to be a male connector, and the extended interface card 3 of the rack server 100 is able to be a female connector, or vice versa. Since it can be deduced and understood by a person having general knowledge in the technical field, it is not going to be further illustrated herein.

The rack server 100 of the present invention can effectively solve the conventional problems which the PCI-E card like extended interface card is aligned with the blade server in slots and occupy one slot space of the rack server such that reduces the amount of slot of the rack server. Furthermore, the expansion amounts of the server are limited, and the manufacturing costs would be increased for additionally equipping a structure of the rear plate. Therefore, by interconnecting the connector of extended interface card to the connector of the server, the extended interface card is connected to the rear end of the server and a straight line is formed such that the extended interface card does not occupy the space of a server slot so as to correspondingly increase a number of slots installed in a unit area and save the manufacturing costs.

The examples described hereinabove are merely provided to exemplary illustrate the characteristic and utility of the present invention, and are not used for limiting the scope of substantial technical content of the present invention. The scope of substantial technical content of the present invention should be generally defined as the following claims, and any technical embodiments or methods which is totally the same or is an equivalent modification of that defined in the following claims by anyone should be considered as containing in the claims. For example, the method of connecting the server and the extended interface card in the present invention may be achieved by using any equivalent connecting interfaces which can interconnect the server to the extended interface card, and should not be limited in the disclosures of the present example.

What is claimed is:

1. A rack server comprising:
a rack case comprising:
a front surface having a plurality of server slots for insertion of a plurality of servers; and
a rear surface having a plurality of card slots corresponding to the server slots for insertion of a plurality of extended interface cards;
at lease a server inserted into one of the server slots, the server having a rear end connected to a server connector; and
at least an extended interface card inserted into one of the card slots, the extended interface card having a card connector for electrically connecting to the server connector of the server.

2. The rack server according to claim 1, wherein the server is a blade server.

3. The rack server according to claim 1, wherein the extended interface card is a peripheral component interconnect-enhanced (PCI-E) card.

4. The rack server according to claim 1, wherein the server connector of the server is a slot.

5. The rack server according to claim 1, wherein the card connector of the extended interface card is a plugging terminal.
